(19) United States
(12) Patent Application Publication
(10) Pub. No.: US 2002/0134423 A1
(43) Pub. Date: Sep. 26, 2002

(54) Membrane-based solar array structures for spacecraft

(76) Inventors: Howard S. Eller, Redondo Beach, CA (US); Martin M. Giebler, Redondo Beach, CA (US)

Correspondence Address: Connie M. Thousand, TRW Inc., Law Dept., One Space Park, Bldg. E2/6051, Redondo Beach, CA, 90245, US

(21) Appl. No.: 09/815,811

(22) Filed: Mar. 23, 2001

(51) Int. Cl. H01L 31/00

(52) U.S. Cl. 136/245; 136/244; 136/251; 136/292

(57) ABSTRACT

A spacecraft solar array structure including at least one sheet of amorphous silicon (12, 24, 34) formed on a flexible backing film, a supporting structure (14, 22, 36), and a mechanism for reducing the bulk of the solar array structure to facilitate storage for launch and deployment of the structure in space. One disclosed embodiment of the invention includes a sheet of solar array material that deploys as cylindrical array (12) that does not need to be mounted on gimbals. In another embodiment, the solar array (24) is disposed on a rear surface of an antenna dish (22). In yet another embodiment, the supporting structure of the solar array (34) includes multiple antenna dipole elements (36).

### BACKGROUND OF THE INVENTION

This invention relates generally to solar arrays for use in space and, more particularly, to solar arrays that must meet relatively high power requirements. Current solar arrays for spacecraft, using conventional silicon cells, are extremely expensive. For high power applications especially, the solar array cost is a significant portion of the total cost of a spacecraft bus, i.e., the total cost of the spacecraft excluding payload components. Conventional silicon solar cells are typically manufactured and supplied in large flat panels, which have two principal disadvantages for use on spacecraft. First, flat panels are difficult to stow for launching and must often be designed to be folded for launch, and later unfolded when deployed in space. Second, flat panels must be pointed toward the sun to maximize power generation. Therefore, systems must be devised to turn the panels toward the sun, or to rotate the whole spacecraft, when generating power.

Accordingly, it would be highly desirable to provide a solar array structure that overcame these disadvantages. The present invention achieves this goal and has additional advantages, as will become apparent from the following summary.

### SUMMARY OF THE INVENTION

The present invention resides in flexible solar array structure for use on spacecraft. Briefly, and in general terms, the invention comprises at least one sheet of membrane-based solar array material; a supporting structure for the membrane-based solar array material; and means for reducing the bulk of the membrane-based solar array material to facilitate stowing for launch and deployment in space. Preferably, the membrane-based solar array material is amorphous silicon formed on a backing film.

In one embodiment of the invention the means for reducing the bulk of the membrane-based solar array material includes a rotatable spindle. One edge of a rectangular sheet of the solar array material is attached to the spindle and an opposite edge is tethered to the spindle. Rotation of the spindle in one direction has the effect of rolling the sheet of material about the spindle for compact storage, and rotation of the spindle in the opposite direction deploys the sheet as a cylindrical array presenting active solar cells in all directions about a longitudinal axis.

In another embodiment of the invention, the supporting structure includes at least one antenna dish; and the sheet of solar array material is attached to a rear face of the supporting antenna dish. In a third embodiment of the invention, the supporting structure includes a plurality of dipole antenna elements.

It will be appreciated that the present invention represents a significant advance in the field of solar array design for use on spacecraft. In particular, the invention provides a solar array that is light in weight, low in cost, and extremely easy to stow for launch and to deploy in space. Moreover, use of the solar array in space reduces or eliminates the need to articulate solar panels by gimbals or other means, because the array is flexible enough to conform with curved surfaces that can receive solar energy from practically any direction. Other aspects and advantages of the invention will become apparent from the following more detailed description, taken in conjunction with the accompanying drawings.

### BRIEF DESCRIPTION OF THE DRAWINGS

FIG. 1 is a simplified three-dimensional view of a spacecraft with two cylindrical solar arrays in accordance with one embodiment of the present invention;

FIG. 2 is a simplified three-dimensional view of a spacecraft with four solar arrays mounted on the backs of dish antennas in accordance with another embodiment of the present invention; and

FIG. 3 is a simplified three-dimensional view of a solar array structure in which antenna dipoles are integrated within the solar array and operated as a single structure, in accordance with a third embodiment of the present invention.

### DESCRIPTION OF THE PREFERRED EMBODIMENTS

As shown in the drawings for purposes of illustration, the present invention pertains to solar arrays for use on spacecraft. In the past, solar arrays using conventional silicon cells have been bulky and were configured as flat panels, which are difficult to stow for launching and require frequent realignment with the sun for most efficient use.

In accordance with the present invention, spacecraft solar arrays are structured to use amorphous silicon sheets instead of conventional silicon photocells. Although amorphous silicon has used or proposed for use in a number of terrestrial applications, it has not been used in space, perhaps because of its relatively low energy conversion efficiency, which is about half that of conventional solar arrays. However, amorphous silicon or other membrane-based solar arrays have a number of advantages over conventional solar arrays, and give rise to several new spacecraft configurations, three of which are illustrated and described in this specification.

Amorphous silicon is fabricated on a thin and flexible membrane of a material such as Mylar. Silicon cells are basically printed on the membrane using conventional photolithographic techniques. Also printed on the membrane are conductive traces that connect the individual cells in rows or columns. The membrane may be fabricated as a continuous sheet and stored in the form of a roll.

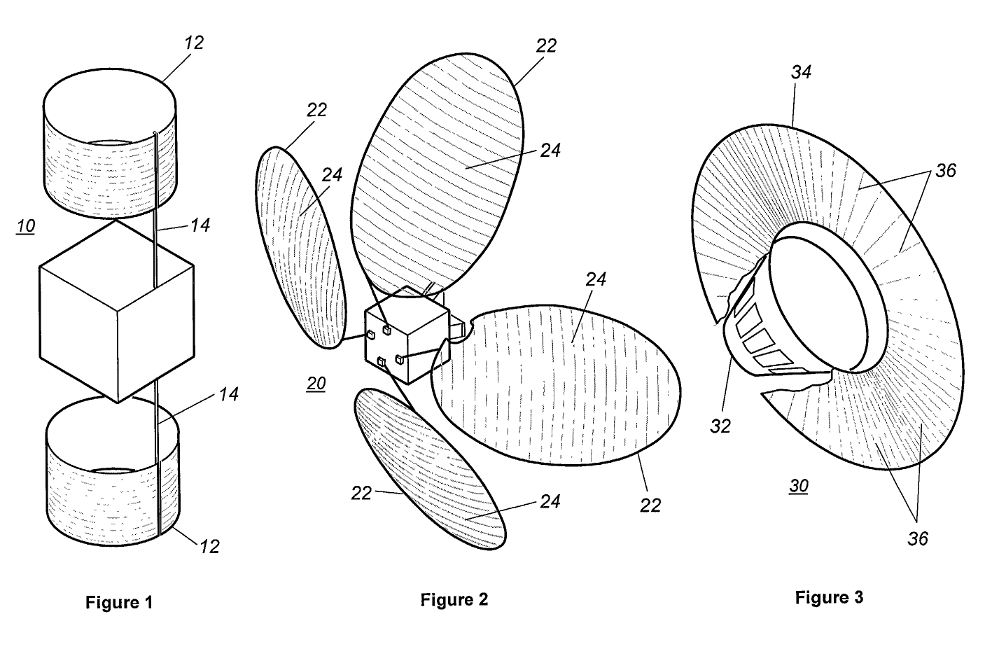

FIG. 1 shows one embodiment of the invention, in which a spacecraft, indicated by reference numeral 10, has two cylindrical solar arrays 12, each of which is mounted on a spindle 14 structurally connected to the spacecraft. One advantage of this configuration is that each array 12 can be rolled on its spindle 14 for stowage during launching of the vehicle. When the vehicle 10 reaches its operational orbit, the spindles 14 are rotated to deploy the arrays 12. The deployment operation is analogous to the function of a house window shade, except that the free end of the “shade,” in the form of the sheet of amorphous silicon, is tethered to remain close to the spindle 14. Thus, as the spindle rotates to deploy the array 12, the amorphous silicon membrane forms an approximate cylinder, which expands in diameter as the deployment continues. It will be understood that, in most applications, the arrays 12 will need to be deployed only once.

The cylindrical arrays 12 have the additional advantage that they are equally effective over a wide range of spacecraft orientations. If the longitudinal axis of the cylindrical arrays 12 is aligned with the north-south axis of the spacecraft 10, the sun effectively “walks” around the fixed array cylinders of the spacecraft as it moves in orbit. At least a portion of each cylindrical array 12 is illuminated continuously, except in eclipse, so there is no need to gimbal the arrays. Obviously, the arrays 12 are ineffective if the spacecraft is oriented such that the sun is aligned along or near the longitudinal axis of the cylinders. Even this limitation is avoided if the two arrays 12 are oriented with their longitudinal axes perpendicular to each other.

Another advantage of the use of membrane-based solar arrays is that they may be conveniently conformed to the surface of an existing structure, such as an antenna dish. FIG. 2 shows a spacecraft 20 with four deployed antennas 22, and with amorphous silicon solar arrays 24 mounted to the back surfaces of the antennas. The antennas 22 are folded in any conventional manner for launch, and deployed into dish-like configurations in space. The amorphous silicon film solar arrays 24 fold and deploy as part of the structure of the antennas 22. Although the solar arrays 24 are shown as being co-extensive with the antennas 22, in many applications the solar arrays need to occupy only a fraction of the antenna surface or antenna reflector structure edge.

FIG. 3 shows a third embodiment of the invention, in which a spacecraft 30 includes a frusto-conical structure 32 on which is mounted an annular solar array 34 of amorphous silicon. Integrated into the solar array can be a plurality of antenna dipole elements 36 that perform a dual function as antenna elements and solar array supporting structure. This embedded antenna within the solar array 34 is well suited for operation in low earth orbit (LEO), where relatively low antenna gain is required. Again, the array 34 is conveniently folded for launch, and deployed in space when an operational orbit is reached.

It will be appreciated from the foregoing that the present invention represents a significant advance in the field of spacecraft design. In particular, the invention provides solar arrays that are low in cost, light in weight, and are conveniently stowed for launch and deployable in space. It will also be appreciated that, although specific embodiments of the invention have been described by way of illustration, various modifications may be made without departing from the spirit and scope of the invention. Accordingly, the invention should not be limited except as by the appended claims.

What is claimed is:

1. A spacecraft solar array, comprising:
at least one sheet of membrane-based solar array material;
a supporting structure for the membrane-based solar array material; and
means for reducing the bulk of the membrane-based solar array material to facilitate stowing for launch and deployment in space.

2. A spacecraft solar array, comprising:
at least one sheet of amorphous silicon membrane-based solar array material formed on a backing film;
a supporting structure for the amorphous silicon membrane-based solar array material; and
means for reducing the bulk of the amorphous silicon membrane-based solar array material to facilitate stowing for launch and deployment in space.

3. A spacecraft solar array, comprising:
at least one sheet of membrane-based solar array material;
a supporting structure for the membrane-based solar array material; and
means for reducing the bulk of the membrane-based solar array material to facilitate stowing for launch and deployment in space wherein the means for reducing the bulk of the membrane-based solar array material includes a rotatable spindle;
one edge of a rectangular sheet of the solar array material is attached to the spindle and an opposite edge is tethered to the spindle; and
rotation of the spindle in one direction has the effect of rolling the sheet of material about the spindle for compact storage, and rotation of the spindle in the opposite direction deploys the sheet as a cylindrical array presenting active solar cells in all directions from a longitudinal axis.

4. A spacecraft solar array, comprising:
at least one sheet of membrane-based solar array material;
a supporting structure for the membrane-based solar array material including at least one antenna reflector with the sheet of solar array material being attached to a face of the supporting antenna reflector; and
means for reducing the bulk of the membrane-based solar array material to facilitate stowing for launch and deployment in space.

5. A spacecraft solar array as defined in claim 1, wherein:
the supporting structure includes a plurality of dipole antenna elements.

6. A spacecraft solar array, comprising:
at least one sheet of amorphous silicon membrane-based solar array material formed on a backing film;
a supporting structure for the amorphous silicon membrane-based solar array material including at least one antenna reflector with the sheet of solar array material being attached to a face of the supporting antenna reflector; and;
means for reducing the bulk of the amorphous silicon membrane-based solar array material to facilitate stowing for launch and deployment in space wherein the means for reducing the bulk of the membrane-based solar array material includes a rotatable spindle;
one edge of a rectangular sheet of the solar array material being attached to the spindle and an opposite edge being tethered to the spindle; and
rotation of the spindle in one direction has the effect of rolling the sheet of material about the spindle for compact storage, and rotation of the spindle in the opposite direction deploys the sheet as a cylindrical array presenting active solar cells in all directions from a longitudinal axis.
